(19) United States
(12) Patent Application Publication
(10) Pub. No.: US 2026/0058622 A1
(43) Pub. Date: Feb. 26, 2026

(54) Ripple Reduction Using Chopper Amplifiers

(71) Applicant: TEXAS INSTRUMENTS INCORPORATED, Dallas, TX (US)

(72) Inventors: Boqiang Xiao, Plano, TX (US); Nan Xing, Allen, TX (US)

(21) Appl. No.: 19/305,479

(22) Filed: Aug. 20, 2025

Related U.S. Application Data
(60) Provisional application No. 63/685,980, filed on Aug. 22, 2024.

(51) Int. Cl. H03F 3/45; H03F 1/26; H03H 11/04; H03H 11/12

(52) U.S. Cl. CPC H03F 3/45986; H03F 1/26; H03F 3/45475; H03H 11/1217; H03F 2200/267; H03F 2200/271; H03F 2200/375; H03F 2200/459; H03H 2011/0488

(57) ABSTRACT

Described embodiments include an apparatus with a first amplifier having first inputs and first outputs. A second amplifier has second inputs and a second output. A first chopper circuit is coupled between third inputs and the first inputs. A second chopper circuit is coupled between the first outputs and the second inputs. A balanced filter is coupled to the second inputs.

### CROSS-REFERENCE TO RELATED APPLICATION

This application claims priority to U.S. Provisional Patent Application No. 63/685,980 filed Aug. 22, 2024, which is incorporated herein by reference in its entirety.

### TECHNICAL FIELD

The present disclosure relates generally to electronic circuits and systems, and in particular embodiments, to circuits and techniques for reducing ripple while maintaining adequate bandwidth in amplifiers.

### BACKGROUND

Some systems perform a data acquisition followed by a digitization of the data with an analog-to-digital converter (ADC) or some other type of sampling circuit. An example of such a system is a battery voltage monitor for electric vehicle systems. It is usually considered not best practice to drive the ADC directly from the data sensing terminal because it may interfere with the data acquisition and have an impact on the accuracy of the data. Rather, it may be better to isolate and buffer the data acquisition node from the ADC. In such systems, the data may be provided to an amplifier that drives the ADC or sampling circuit.

The amplifier used to drive the ADC can have relatively high precision and bandwidth. High precision may imply low offset and low ripple in the amplifier. A chopper amplifier can be used to achieve low offset while providing adequate bandwidth for the application. However, chopper amplifiers can result in increased ripple due to switching, which can compromise the accuracy of the amplifier.

### SUMMARY

In a first example, an apparatus includes a first amplifier having first inputs and first outputs. A second amplifier has second inputs and a second output. A first chopper circuit is coupled between third inputs and the first inputs. A second chopper circuit is coupled between the first outputs and the second inputs. A balanced filter is coupled to the second inputs.

In a second example, an apparatus includes a chopper circuit having inputs and outputs, and includes a first chopper and a second chopper. A feedforward circuit has inputs coupled to the inputs of the chopper circuit, and has outputs. An output circuit has inputs coupled to the outputs of the chopper circuit and the outputs of the feedforward circuit. A balanced filter is coupled to the outputs of the second chopper.

In a third example, a system includes a first amplifier having first inputs and first outputs. A first resistor is coupled between an input voltage terminal and a first one of the first inputs. A second resistor is coupled between the first one of the first inputs and a reference voltage terminal. A second amplifier has second inputs and a second output. A first chopper circuit is coupled between third inputs and the first inputs.

A second chopper circuit is coupled between the first outputs and the second inputs. A balanced filter is coupled to the second inputs. An analog-to-digital converter (ADC) has an input coupled to the output of the second amplifier. A third resistor is coupled between the input of the ADC and a second one of the first inputs. A fourth resistor is coupled between the second one of the first inputs and a ground terminal.

### BRIEF DESCRIPTION OF THE DRAWINGS

For a more complete understanding of the present disclosure, and the advantages thereof, reference is now made to the following descriptions taken in conjunction with the accompanying drawings.

FIG. 1 shows a schematic diagram for an example chopper amplifier circuit with a balanced filter.

FIG. 2 shows a block diagram for an example chopper circuit.

FIG. 3A shows a schematic diagram for an example chopper amplifier circuit having a balanced resistor-capacitor (R-C) filter.

FIG. 3B shows a schematic diagram for an example chopper amplifier circuit having a balanced R-C filter with Miller capacitance multiplication using single-output inverting amplifiers.

FIG. 4 shows a schematic diagram for an example chopper amplifier circuit having a balanced filter with Miller capacitance multiplication using a differential amplifier.

FIG. 5 shows a schematic diagram for an example chopper amplifier circuit having a balanced filter and a parallel feedforward path to increase bandwidth.

FIG. 6 shows a schematic diagram for an example chopper amplifier circuit having a balanced filter, a parallel feedforward path to increase bandwidth, and an AC feedback circuit to further reduce ripple.

FIG. 7 shows a schematic diagram for an example chopper amplifier circuit having a balanced filter using Miller capacitance multiplication, a parallel feedforward path to increase bandwidth, and an AC feedback circuit to further reduce ripple.

FIG. 8 shows a Bode plot for three example stages of a chopper amplifier circuit.

FIG. 9 shows a Bode plot for an example chopper amplifier circuit with and without a balanced filter using Miller capacitance multiplication.

FIG. 10 shows a block diagram for an example battery voltage monitor using a chopper amplifier circuit.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

An amplifier used to drive an ADC in a data acquisition system usually has relatively high precision and bandwidth. The bandwidth needed for a particular application can depend on the acquisition time of the ADC being driven and whether it is a fast-sampling ADC. For example, a sigma-delta ADC may not require a particularly high bandwidth because it averages a relatively large number of samples. But a successive-approximation-register (SAR) ADC may perform its acquisition over a small number (e.g. 1 or 2) of clock periods at the frequency it is clocked at, which may be only a few microseconds.

A high-precision amplifier usually has low offset and low ripple. A chopper amplifier can be used to achieve low offset while providing adequate bandwidth for the application. An advantage that a chopper amplifier provides is that any offset drift that occurs from a change in system parameters such as common mode voltage level can be canceled out. However, the use of chopper amplifiers may result in increased ripple due to switching, which can compromise the accuracy of the amplifier if the increased ripple is not mitigated.

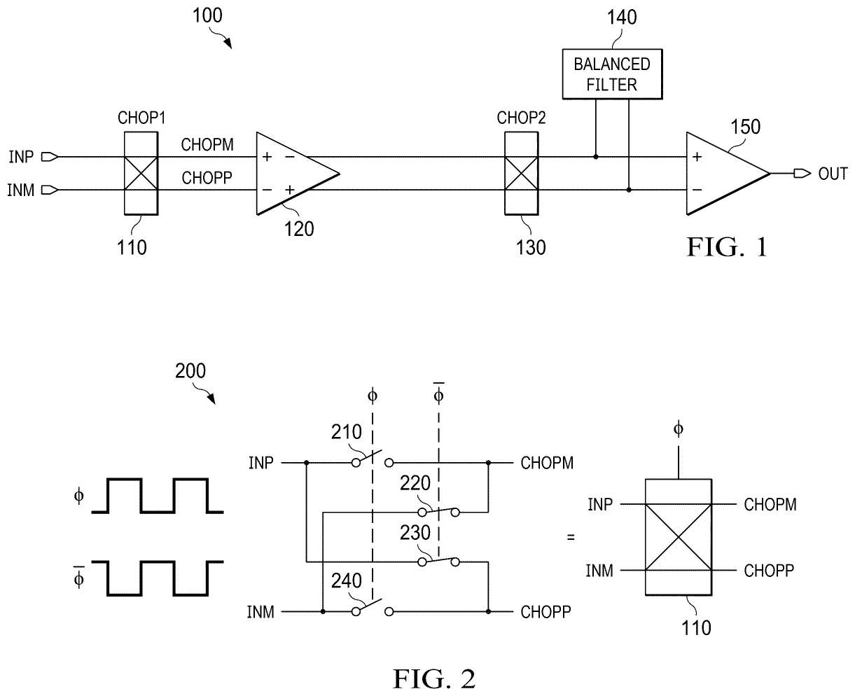

FIG. 1 shows a schematic diagram for an example chopper amplifier circuit 100. Chopper amplifier circuit 100 includes a first chopper circuit 110, a second chopper circuit 130, differential amplifier 120, amplifier 150 and balanced filter 140. Chopper circuit 110 has a differential input INP and INM to receive input signals (e.g., differential signals) from a data source, such as a battery voltage measurement. The differential outputs of chopper circuit 110 are coupled to respective inputs of differential amplifier 120. The differential outputs of differential amplifier 120 are coupled to respective inputs of chopper circuit 130. The differential outputs of chopper circuit 130 are coupled to the inputs of balanced filter 140 and amplifier 150, as shown in FIG. 1. Amplifier 150 can have a pair of matched/differential inputs and an output (labelled “OUT”). Balanced filter 140 can include a pair of matched filter circuits coupled to the differential outputs of chopper circuit 130 and to the differential/matched inputs of amplifier 150. The balanced filter 140 can be a low pass filter with a 3 dB frequency (or a dominant pole frequency) based on the switching/chopping frequency of chopper circuit 110, to attenuate the ripple at the output of second chopper circuit 130.

FIG. 2 shows a block diagram for an example chopper circuit 200 that may be used for chopper circuit 110 or chopper circuit 130. Chopper circuit 200 includes switches 210, 220, 230 and 240. Chopper circuit 200 receives the differential input signals and provides differential output signals CHOPP AND CHOPM which have an inverted polarity from the input signals due to the chopping function.

Switches 210 and 240 are controlled by a clock signal Φ which is provided by a clock generator circuit (not shown). Switches 220 and 230 are controlled by a signal [symbol] which is the inverted version of Φ. Clock signals Φ and [symbol] are each square waves having 50% duty cycle with a frequency of f_{chop}. During a first half-cycle, switches 210 and 240 are closed and switches 220 and 230 are open. During a second half-cycle, switches 210 and 240 are open and switches 220 and 230 are closed.

Switches 210 and 240 and switches 220 and 230 are constantly switching back and forth while the chopper is operating. Use of a chopper can improve the accuracy of an amplifier because any offset drift that occurs is canceled out by the chopper. This is done by taking any common-mode offset between the differential inputs and alternately inverting back and forth.

For example, if the voltages at the inputs INP and INM were 5 mV apart, then the outputs of chopper circuit 200 would continually toggle back and forth +/−5 mV, making the average offset voltage zero. In the absence of a chopper in the amplifier circuit, the 5 mV offset would be passed on and gained up by differential amplifier 120 leaving a constant offset voltage in the amplifier. Chopping takes the offset voltage and flips its polarity back and forth between positive and negative at the same amplitude, driving the average offset voltage to zero.

In FIG. 1, differential input signals at inputs INP and INM are provided to chopper circuit 110 which provides differential output signals CHOPP and CHOPM which are an inverted version of the inputs with any offset removed. The signals CHOPP and CHOPM are provided to the inputs of differential amplifier 120 which may provide gain in some cases. The outputs of differential amplifier 120 are coupled to the inputs of chopper circuit 130. Because the outputs of a chopper circuit are inverted in polarity from its inputs, any circuit that has a first chopper circuit must have a second chopper circuit to invert the signals back to their original polarity. Otherwise, the output of the amplifier will have the wrong polarity.

The differential outputs of chopper circuit 130 are coupled to the inputs of balanced filter 140 and the inputs of amplifier 150, whose output is the output of chopper amplifier circuit 100. The signals at the outputs of chopper circuit 130 contain ripple. A first source of ripple is the chopping ripple that occurs at the chopping frequency. For example, if the chopping frequency is 100 kHz, a 100 kHz ripple signal may be present on the output signal of chopper circuit 130. A second source of ripple at the outputs of chopper circuit 130 is a higher frequency (e.g. 1 Ghz) ringing that occurs at the edge of every clock period. Balanced filter 140 receives the signals at the outputs of chopper circuit 130 and filters a portion of the chopping ripple. Balanced filter 140 removes noise at the chopping frequency and beyond, and may have any one of many possible configurations and frequency responses.

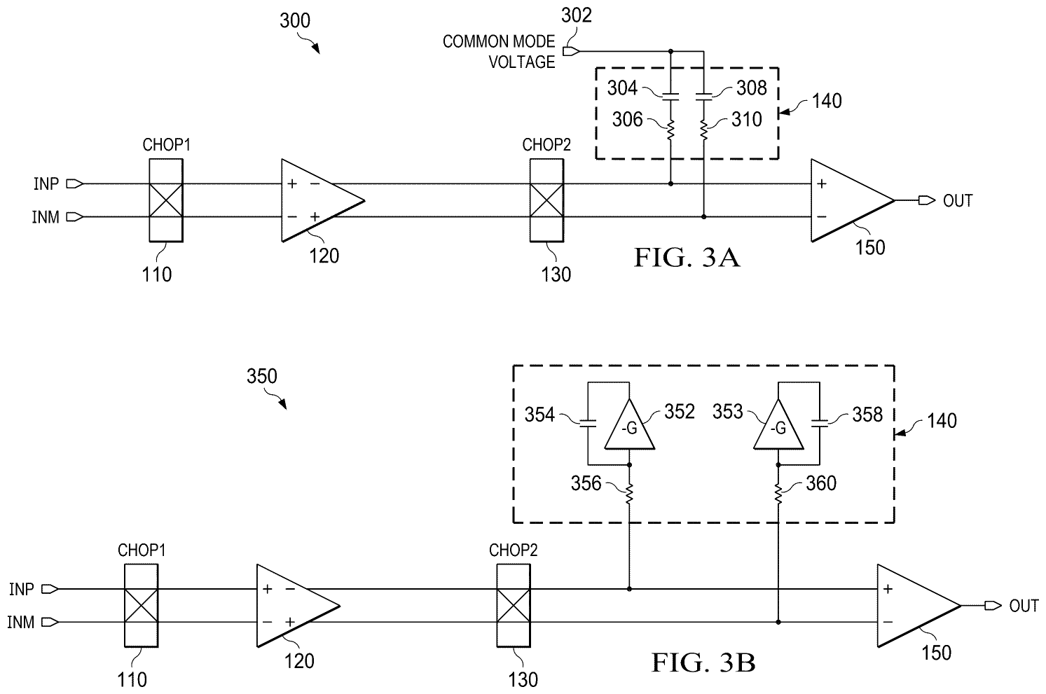

FIG. 3A shows a schematic diagram for an example chopper amplifier circuit 300 with a balanced resistor-capacitor (R-C) filter. Chopper amplifier circuit 300 includes first chopper circuit 110, second chopper circuit 130, differential amplifier 120, amplifier 150 and balanced filter 140. Balanced filter 140 includes capacitors 304 and 308 and resistors 306 and 310. Chopper circuit 110 has a differential input that receives analog input signals INP and INM. The differential outputs of chopper circuit 110 are coupled to respective inputs of differential amplifier 120. The differential outputs of differential amplifier 120 are coupled to respective inputs of chopper circuit 130.

Capacitor 304 and resistor 306 are coupled to one of the differential outputs of second chopper circuit 130 and one of the differential inputs of amplifier 150, and capacitor 308 and resistor 310 are coupled to another one of the differential outputs of second chopper circuit 130 and another one of the differential inputs of amplifier 150. The differential outputs of chopper circuit 130 are coupled to first terminals of resistor 306 and resistor 310, respectively. Capacitor 304 is coupled between a second terminal of resistor 306 and a common mode voltage terminal 302. Capacitor 308 is coupled between a second terminal of resistor 310 and common mode voltage terminal 302. Common mode voltage terminal 302 may be at ground or at some other voltage. Capacitor 304 combined with resistor 306 form a first lowpass filter. Capacitor 304 is matched with capacitor 308 (e.g., having the same capacitance, having the same geometry, made of the same material, and/or being interdigitated with each other), and resistor 306 is also matched with resistor 310 (e.g., having the same resistance, having the same geometry, made of the same material, and/or being interdigitated with each other). Together these resistors and capacitors form a balanced filter on the differential output of chopper circuit 130 and provide the filtered signals to the inputs of amplifier 150.

A relatively large capacitance (i.e. >200 pF) may be needed in capacitors 304 and 308 to sufficiently filter out the chopping ripple. Capacitors of this size can be relatively large and take up a significant amount of space on the die that implements chopper amplifier circuit 300. A more area-efficient configuration for creating that value of capacitance can be obtained using the Miller effect. The Miller effect allows the use of a smaller capacitor whose capacitance is gained up by the gain of the amplifier to achieve a larger effective capacitance.

FIG. 3B shows a schematic diagram for an example chopper amplifier circuit 350 having a balanced R-C filter with Miller capacitance multiplication using single-output inverting amplifiers. Chopper amplifier circuit 350 includes a first chopper circuit 110, a second chopper circuit 130, differential amplifier 120, amplifier 150 and balanced filter 140. Balanced filter 140 includes single-output inverting amplifiers 352 and 353, capacitors 354 and 358 and resistors 356 and 360. Chopper circuit 110 has differential inputs coupled to INP and INM to receive input signals. The differential outputs of chopper circuit 110 are coupled to respective inputs of differential amplifier 120. The differential outputs of differential amplifier 120 are coupled to respective inputs of chopper circuit 130.

The differential outputs of chopper circuit 130 are coupled to first terminals of resistor 356 and resistor 360, respectively. A second terminal of resistor 356 is coupled to the input of single-output inverting amplifier 352. Capacitor 354 is coupled between the output of single-output inverting amplifier 352 and the second terminal of resistor 356. A second terminal of resistor 360 is coupled to the input of single-output inverting amplifier 353. Each of inverting amplifiers 352 and 353 may include a single-stage amplifier such as, for example, a push-pull amplifier, or a common source/common emitter amplifier with a current source. Capacitor 358 is coupled between the output of single-output inverting amplifier 353 and the second terminal of resistor 360. Capacitors 354 and 358 have the same capacitance and resistors 356 and 360 have the same resistance. The first terminal of resistor 356 is coupled to a first input of amplifier 150, and the first terminal of resistor 360 is coupled to second input of amplifier 150. Each of the inverting amplifiers 352 and 353 can amplify the effective capacitances of, respectively, capacitors 354/358 by a factor equal to the gain of the amplifier, due to Miller effect, which allows the sizes of capacitors 354 and 358 to be reduced and facilitates implementation of these capacitors on die. Such arrangements can reduce the overall system size and reduce the interconnect parasitics between capacitors 354 and 358 and the rest of the circuit.

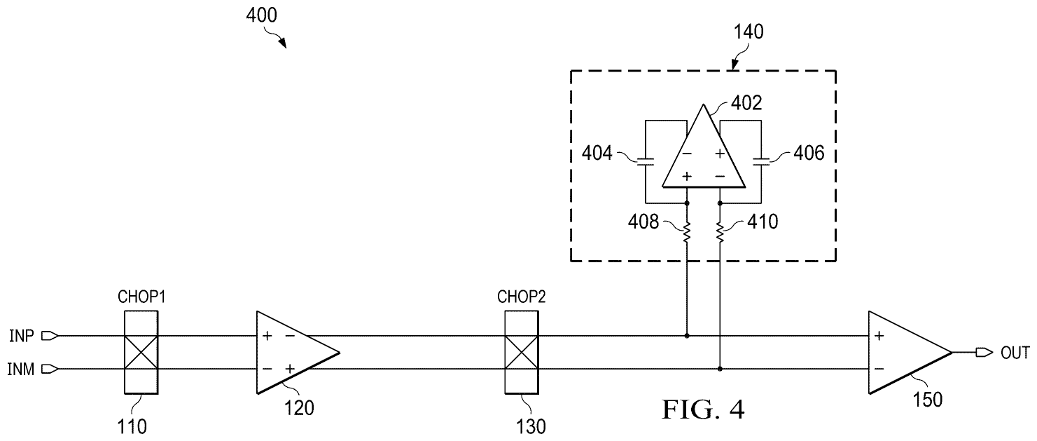

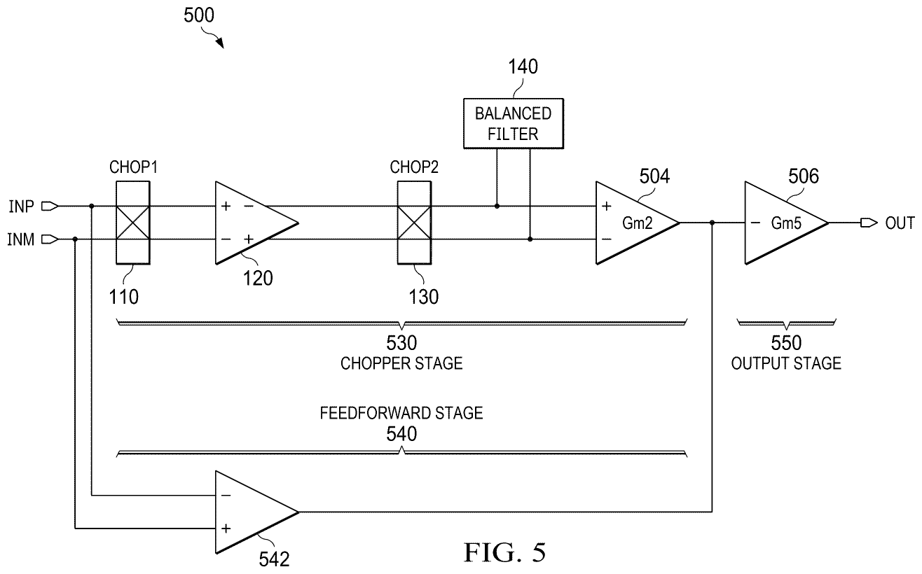

FIG. 4 shows a schematic diagram for an example chopper amplifier circuit 400 having a balanced filter with Miller capacitance multiplication using a differential amplifier. Chopper amplifier circuit 400 includes a first chopper circuit 110, a second chopper circuit 130, differential amplifier 120, amplifier 150 and balanced filter 140. Balanced filter 140 includes fully differential amplifier 402, resistors 408 and 410, and capacitors 404 and 406. Chopper circuit 110 has a differential input that receives analog input signals INP and INM. The differential outputs of chopper circuit 110 are coupled to respective inputs of differential amplifier 120. The differential outputs of differential amplifier 120 are coupled to respective inputs of chopper circuit 130.

The differential outputs of chopper circuit 130 are coupled to first terminals of resistor 408 and resistor 410, respectively. A second terminal of resistor 408 is coupled to the non-inverting input of differential amplifier 402. A second terminal of resistor 410 is coupled to the inverting input of differential amplifier 402. Capacitor 404 is coupled between the non-inverting input of amplifier 402 and the negative output of amplifier 402. Capacitor 406 is coupled between the inverting input of amplifier 402 and the positive output of amplifier 402. The respective capacitances of capacitors 404 and 406 are the same, and the respective resistances of resistors 408 and 410 are the same. This circuit uses the Miller effect in a differential amplifier to multiply the effective capacitance of capacitors 404 and 406, similar to the arrangements in FIG. 3B.

The capacitance of a capacitor connected between the input and output of an amplifier is multiplied by the gain of the amplifier to provide an effectively larger capacitance. For example, if capacitors 404 and 406 are each 10 pF capacitors and the gain of amplifier 402 is 60, the effective capacitance of capacitors 404 and 406 is 60×10 pF or 600 pF. Using the Miller effect, a capacitance of 600 pF is obtained in only the silicon area required for a 10 pF capacitor. This is a frequency-dependent effect, so the effective capacitance is dependent on the gain of amplifier 402 at the chopping frequency when considering how much attenuation of the chopping ripple that balanced filter 140 will provide to chopper amplifier circuit 400.

A benefit of chopper amplifier circuit 400 compared to chopper amplifier circuit 300 is the ability to provide the same amount of chopping ripple attenuation in a smaller silicon area. A benefit of balanced filter 140 in chopper amplifier circuit 400 compared to the balanced filter 140 in chopper amplifier 350 is the differential amplifier's ability to balance asymmetric noise/ripple between the two inputs better than with two single-ended inputs. Chopper amplifier circuits 100, 300, 350 and 400 are each relatively low noise and low bandwidth amplifiers. For applications needing both low noise and high bandwidth, a separate high-bandwidth feedforward stage can be added in parallel with the chopper stage to increase the bandwidth without decreasing the ripple rejection. Moreover, using a fully differential amplifier 402, which may include matched differential circuitries to provide the Miller amplification can further improve the balancing/in the signal at the output of chopper 130. On the other hand, using a single stage inverting amplifier to provide the Miller amplification, as shown in FIG. 3B, can provide reduced circuit complexity.

FIG. 5 shows a schematic diagram for an example chopper amplifier circuit 500 with a balanced filter using Miller capacitance multiplication and having a parallel feedforward path to increase bandwidth. Chopper amplifier circuit 500 includes chopper stage 530, feedforward stage 540 and an output stage 550. Chopper stage 530 includes a first chopper circuit 110, a second chopper circuit 130, differential amplifier 120, amplifier 504, and balanced filter 140. Feedforward stage 540 includes amplifier 542. Output stage 550 includes amplifier 506.

Chopper circuit 110 has a differential input that receives analog input signals INP and INM. The differential outputs of chopper circuit 110 are coupled to respective inputs of differential amplifier 120. The differential outputs of differential amplifier 120 are coupled to respective inputs of chopper circuit 130. The differential outputs of chopper circuit 130 are coupled to the inputs of balanced filter 140 and the inputs of amplifier 504.

The output of amplifier 504 is coupled to the input of amplifier 506, whose output provides the output signal OUT of chopper amplifier circuit 500. Amplifier 542 has differential inputs receiving input signals INP and INM. The output of amplifier 542 is coupled to the input of amplifier 506.

The configuration of chopper amplifier circuit 500 helps to provide higher accuracy due to lower offset and ripple and further provides higher bandwidth than chopper amplifier circuit 100 or chopper amplifier circuit 300. The bandwidth of chopper stage 530 is limited by the relatively low bandwidth of chopper circuit 110 and chopper circuit 130. Chopper stage 530 and output stage 550 provide a relatively low offset path with relatively low bandwidth, and feedforward stage 540 provides a higher bandwidth path. The combination of the two parallel paths provides low offset and high bandwidth for chopper amplifier circuit 500.

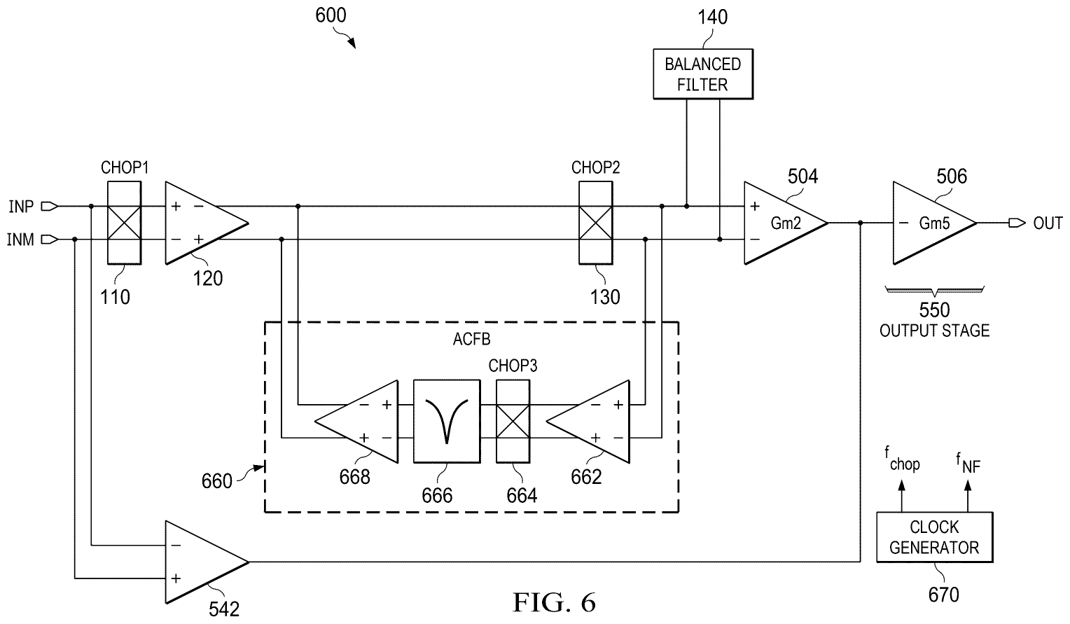

FIG. 6 shows a schematic diagram for an example chopper amplifier circuit 600 with a balanced filter, a parallel feedforward path to increase bandwidth, and an AC feedback circuit 660 to further reduce ripple and chopping noise. Chopper circuit 110 has differential inputs coupled to INP and INM to receive input signals. The differential outputs of chopper circuit 110 are coupled to respective inputs of differential amplifier 120. The differential outputs of differential amplifier 120 are coupled to respective inputs of chopper circuit 130. The differential outputs of chopper circuit 130 are coupled to the inputs of balanced filter 140 and the inputs of amplifier 504.

The output of amplifier 504 is coupled to the input of amplifier 506, whose output is coupled to the output (labelled OUT) of chopper amplifier circuit 600. Amplifier 542 has differential inputs coupled to INP and INM to receive input signals. The output of amplifier 542 is coupled to the input of amplifier 506.

AC feedback circuit 660 has differential inputs coupled to the outputs of chopper circuit 130 and differential outputs coupled to the inputs of chopper circuit 130. AC feedback circuit 660 includes differential amplifiers 662 and 668, chopper circuit 664, and notch filter 666. The inputs of differential amplifier 662 are coupled to the outputs of chopper circuit 130. The outputs of differential amplifier 662 are coupled to the inputs of chopper circuit 664. The outputs of chopper circuit 664 are coupled to the inputs of notch filter 666. The outputs of notch filter 666 are coupled to the inputs of differential amplifier 668, and the outputs of differential amplifier 668 are coupled to the inputs of chopper circuit 130.

Differential amplifier 662 buffers the signals at the output of chopper circuit 130 and drives the inputs of chopper circuit 664. Chopper circuit 664 provides further offset reduction and signal polarity inversion to match the polarity of the signals at the output of differential amplifier 120 that are being summed with the output signals of AC feedback circuit 660. Clock generator 670 provides clock signals f_{chop} for clocking chopper circuits 110, 130, and 664. In some examples, f_{chop} may comprise multiple clock signals having the same frequency with different phases. Clock generator 670 also provides a signal f_{NF} that provides a clocking signal for notch filter 666.

Notch filter 666 attenuates the switching noise specifically at the frequency at which the chopper amplifier is being chopped at. For example, if the chopper circuits (i.e. 110, 130, and 664) are operating at 100 KHz, then notch filter 666 is configured to have a frequency response with maximum attenuation at 100 KHz to reduce chopping noise in the circuit. In some examples, notch filter 666 is a switched-capacitor filter. Differential amplifier 668 buffers the output of notch filter 666, and the signals at its output are summed with the output signals of AC feedback circuit 660 and provided to the input of chopper circuit 130. Balanced filter 140 attenuates the noise at the chopping frequency and the high frequency ripple at the edges of every clock period. AC feedback circuit 660 provides further attenuation of the noise at the chopping frequency. In some examples, balanced filter 140 can be configured to attenuate noises at a higher frequency than the chopping frequency, such as the ringing noise and harmonics of the switching noise (at multiples of the chopping frequencies), while AC feedback circuit 600 can attenuate noise at the chopping frequency.

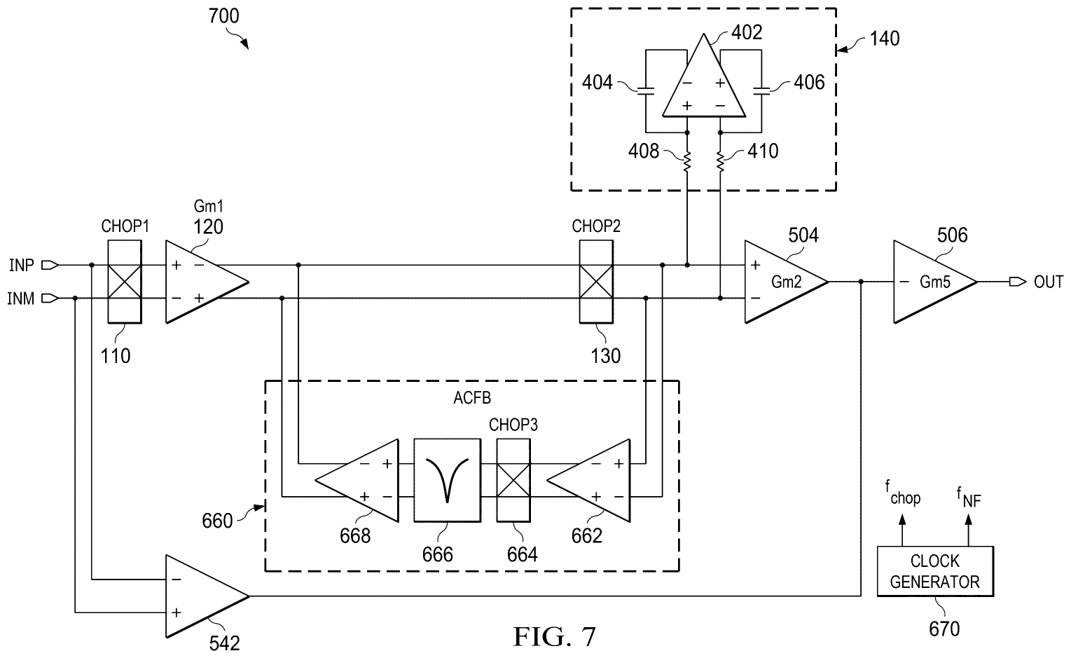

FIG. 7 shows a schematic diagram for an example chopper amplifier circuit 700 with a balanced filter using Miller capacitance multiplication, a parallel feedforward path to increase bandwidth, and an AC feedback circuit to further reduce ripple. Chopper amplifier circuit 700 provides the highest ripple reduction of the examples disclosed herein because balanced filter 140 with Miller capacitance multiplication filters out a large amount of chopper ripple and AC feedback circuit 660 further reduces the chopper offset. Chopper circuit 110 has a differential input that receives input signals at inputs INP and INM. The differential outputs of chopper circuit 110 are coupled to respective inputs of differential amplifier 120. The differential outputs of differential amplifier 120 are coupled to respective inputs of chopper circuit 130. The differential outputs of chopper circuit 130 are coupled to first terminals of resistor 408 and resistor 410, respectively. A second terminal of resistor 408 is coupled to the non-inverting input of differential amplifier 402. A second terminal of resistor 410 is coupled to the inverting input of differential amplifier 402. Capacitor 404 is coupled between the non-inverting input of amplifier 402 and the negative output of amplifier 402. Capacitor 406 is coupled between the inverting input of amplifier 402 and the positive output of amplifier 402. The capacitances of capacitors 404 and 406 are the same, and the resistances of resistors 408 and 410 are the same. This circuit uses the Miller effect in a differential amplifier to multiply the capacitance of capacitors 404 and 406. The differential outputs of chopper circuit 130 are also coupled to the inputs of amplifier 504.

The output of amplifier 504 is coupled to the input of amplifier 506, whose output is coupled to the output terminal (labelled “OUT”) of chopper amplifier circuit 700. Amplifier 542 has differential inputs receiving input signals at INP and INM. The output of amplifier 542 is coupled to the input of amplifier 506 and provides a high bandwidth path. The inputs of differential amplifier 662 are coupled to the outputs of chopper circuit 130. The outputs of differential amplifier 662 are coupled to the inputs of chopper circuit 664. The outputs of chopper circuit 664 are coupled to the inputs of notch filter 666. The outputs of notch filter 666 are coupled to the inputs of differential amplifier 668, and the outputs of differential amplifier 668 are coupled to the inputs of chopper circuit 130.

Differential amplifier 662 buffers the signals at the output of chopper circuit 130 and drives the inputs of chopper circuit 664. Chopper circuit 664 provides further offset reduction and the signal polarity inversion it provides is necessary to match the polarity of the signals at the output of differential amplifier 120 that are being summed with the output signals of AC feedback circuit 660. Clock generator 670 provides clock signals f_{chop} for clocking chopper circuits 110, 130, and 664. In some examples, f_{chop} may comprise multiple signals having the same frequency with different phases. Clock generator 670 also provides a signal f_{NF} that provides clocking for notch filter 666.

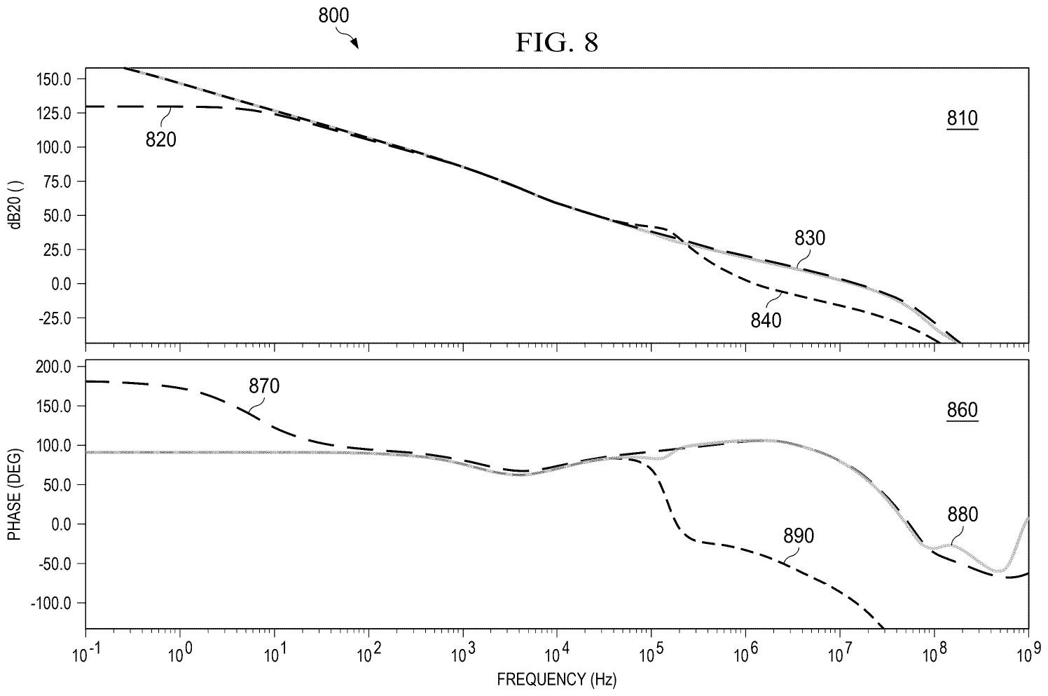

FIG. 8 shows a Bode plot 800 for three example stages of a chopper amplifier circuit such as chopper amplifier circuits 500, 600 or 700. Plot 810 shows graphs of gain versus frequency for each of the three example stages using Miller capacitance multiplication in the balanced filter. Plot 860 shows graphs of phase versus frequency for each of the three example stages using Miller capacitance multiplication in the balanced filter.

Curve 820 shows a graph of gain versus frequency for feedforward stage 540. Curve 840 shows a graph of gain versus frequency for chopper stage 530. Curve 830 shows a graph of gain versus frequency for chopper amplifier circuit 500 using Miller capacitance multiplication in balanced filter 140. Curve 870 shows a graph of phase versus frequency for feedforward stage 540. Curve 890 shows a graph of phase versus frequency for chopper stage 530. Curve 880 shows a graph of phase versus frequency for chopper amplifier circuit 500 using Miller capacitance multiplication in balanced filter 140.

In curve 840, the low frequency chopper stage has higher gain at DC but has low bandwidth, so the gain rolls off at a lower frequency. In curve 820, the high bandwidth feedforward stage has lower gain at DC, but its gain does not roll off until a higher frequency, which provides the amplifier with a higher bandwidth path. In curve 830, the gain of chopper amplifier circuit 500 tracks the maximum of the low frequency chopper stage and the high bandwidth feedforward stage. The loop with the higher gain takes over at any given frequency in chopper amplifier circuit 500.

In curve 840, the gain of the low frequency chopper stage starts to roll off significantly at a particular frequency because it has limited bandwidth due to the limited bandwidth of the chopper circuits. Such a significant roll off in gain also brings a significant dip in the phase response of curve 890. If the low frequency chopper stage (i.e. 530) operates alone, the circuit can go unstable due to this significant dip in the phase response. However, the high bandwidth feedforward stage takes over at the higher frequencies and recovers the phase response of chopper amplifier circuit 500.

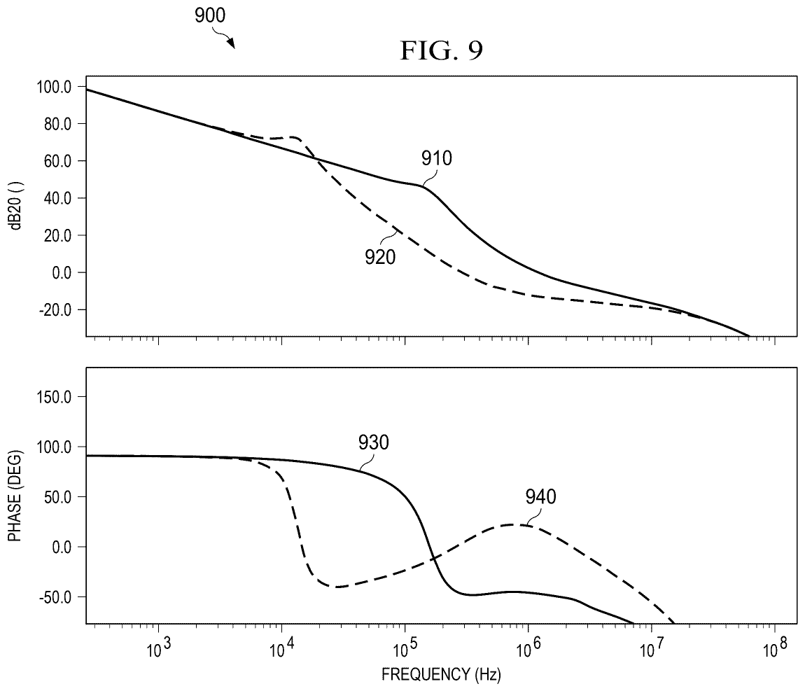

FIG. 9 shows a Bode plot for an example chopper amplifier circuit with and without a balanced filter using Miller capacitance multiplication. Curve 910 shows a graph of gain versus frequency for chopper amplifier circuit 700 without balanced filter 140 using Miller capacitance multiplication. Curve 920 shows a graph of gain versus frequency for chopper amplifier circuit 700 with balanced filter 140 using Miller capacitance multiplication. Curve 930 shows a graph of phase versus frequency for chopper amplifier circuit 700 without balanced filter 140 using Miller capacitance multiplication. Curve 940 shows a graph of phase versus frequency for chopper amplifier circuit 700 with balanced filter 140 using Miller capacitance multiplication.

At all frequencies beyond a certain frequency, the gain is lower in curve 920 with the balanced filter using Miller capacitance multiplication than in curve 910 without the balanced filter using Miller capacitance multiplication. The lower gain with the balanced filter using Miller capacitance multiplication provides additional noise and ripple suppression in this frequency range. In one example, the chopper amplifier circuit with the balanced filter using Miller capacitance multiplication had an 8 dB or 2.5× improvement in noise and ripple suppression. Both in curve 930, the phase response without balanced filter 140 using Miller capacitance multiplication, and in curve 940, the phase response with balanced filter 140 using Miller capacitance multiplication, the roll off frequency in the phase response coincides with the roll off frequency in gain, allowing the feedforward path to take over, keep the global loop stable with adequate phase margin across all frequencies.

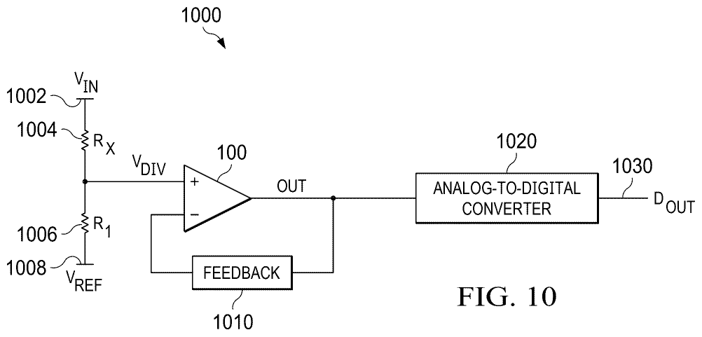

FIG. 10 shows a block diagram for an example battery voltage monitor 1000 using chopper amplifier circuit 100. Voltage terminal 1002 receives a voltage V_{IN}. If the voltage V_{IN} exceeds the maximum input voltage of chopper amplifier circuit 100, the voltage can be divided down to an acceptable level. Resistors 1004 and 1006 form a voltage divider that is coupled between voltage terminal 1002 having a voltage V_{IN} and terminal 1008 having a voltage V_{REF}, which may be at ground or some other voltage.

The center-tap of the voltage divider formed by resistors 1004 and 1006 is coupled to a first input of chopper amplifier circuit 100 and provides a voltage V_{div}. A feedback network 1010 is coupled between the output of chopper amplifier circuit 100 and a second input of chopper amplifier circuit 100. Feedback network 1010 can be a conductor or a resistive voltage divider connected between the output of chopper amplifier circuit 100 and a ground terminal. The output of chopper amplifier circuit 100 is coupled to analog-to-digital converter 1020 where it is digitized. The output 1030 of analog-to-digital converter 1020 provides a digital word D_{OUT} that represents the voltage level of V_{IN}.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” or “configurable to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor components.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be in depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus, comprising:
a first amplifier having first inputs and first outputs;
a second amplifier having second inputs and a second output;
a first chopper circuit coupled between third inputs and the first inputs;
a second chopper circuit coupled between the first outputs and the second inputs; and
a balanced filter coupled to the second inputs.

2. The apparatus of claim 1, wherein the balanced filter includes a first resistor and a first capacitor coupled to a first one of the second inputs and a second resistor and a second capacitor is coupled to a second one of the second inputs.

3. The apparatus of claim 2, wherein the balanced filter includes a third amplifier having third inputs and third outputs, the first capacitor is coupled between a first one of the third inputs and a first one of the third outputs, and the second capacitor is coupled between a second one of the third inputs and a second one of the third outputs.

4. The apparatus of claim 3, wherein the first one of the third inputs and the first one of the third outputs have opposite polarities, and the second one of the third inputs and the second one of the third outputs have opposite polarities.

5. The apparatus of claim 1, further comprising:
a third inverting amplifier having a third input and a third output, the third input coupled to the second output; and
a fourth inverting amplifier having fourth inputs and a fourth output, the fourth inputs coupled to the third inputs, and the fourth output coupled to the second output.

6. The apparatus of claim 5, further comprising:
a fifth amplifier having fifth inputs and fifth outputs, the fifth inputs coupled to the second inputs;
a notch filter having filter inputs and filter outputs;
a third chopper circuit coupled between the fifth outputs and the filter inputs; and
a sixth amplifier having sixth inputs and sixth outputs, the sixth inputs coupled to the filter outputs, and the sixth outputs coupled to the first outputs.

7. The apparatus of claim 1, wherein the first and second chopper circuits are configurable to operate at a chopper frequency, and the balanced filter has a cutoff frequency based on the chopper frequency.

8. The apparatus of claim 6, wherein the first and second choppers operate at a chopper frequency, the notch filter has a notch frequency, and the apparatus is further comprising a clock generator configurable to provide a first clock signal at the chopper frequency and a second clock signal at the notch frequency.

9. An apparatus, comprising:
a chopper circuit having inputs and an output, and including a first chopper and a second chopper;
a feedforward circuit having inputs coupled to the inputs of the chopper circuit, and having outputs;
an output circuit having inputs coupled to the output of the chopper circuit and the output of the feedforward circuit; and
a balanced filter coupled to the outputs of the second chopper.

10. The apparatus of claim 9, wherein the balanced filter includes a differential amplifier, a first capacitor coupled between a first input and a first output of the differential amplifier, and a second capacitor coupled between a second input and a second output of the differential amplifier.

11. The apparatus of claim 9, wherein the chopper circuit includes:
a first amplifier having first inputs and first outputs; and
a second amplifier having second inputs and a second output;
wherein the first chopper is coupled between third inputs and the first inputs, and the second chopper is coupled between the first outputs and the second inputs.

12. The apparatus of claim 11, further comprising an AC feedback (ACFB) circuit that includes:
a third amplifier having third inputs and third outputs, the third inputs coupled to the second inputs;
a notch filter having filter inputs and filter outputs;
a third chopper coupled between the third outputs and the filter inputs; and
a fourth amplifier having fourth inputs and fourth outputs, the fourth inputs coupled to the filter outputs, and the fourth outputs coupled to the first outputs.

13. The apparatus of claim 11, wherein the first and second choppers operate at a chopper frequency, and the balanced filter has a cutoff frequency based on the chopper frequency.

14. The circuit of claim 12, wherein the first, second and third choppers are configurable to operate at a chopper frequency, the notch filter has a notch frequency, and the apparatus further comprises a clock generator configurable to provide a clock signal at the chopper frequency.

15. A system, comprising:
a first amplifier having first inputs and first outputs;
a first resistor coupled between an input voltage terminal and a first one of the first inputs;
a second resistor coupled between the first one of the first inputs and a reference voltage terminal;
a second amplifier having second inputs and a second output;
a first chopper circuit coupled between third inputs and the first inputs;
a second chopper circuit coupled between the first outputs and the second inputs;
a balanced filter coupled to the second inputs;
a feedback network coupled between the second output of the second amplifier and a second one of the first inputs; and
an analog-to-digital converter (ADC) having an input coupled to the second output of the second amplifier.

16. The system of claim 15, wherein the balanced filter includes a third resistor and a first capacitor coupled to a first one of the second inputs and a fourth resistor and a second capacitor coupled to a second one of the second inputs.

17. The system of claim 16, wherein the balanced filter includes a third amplifier having third inputs and third outputs, the first capacitor is coupled between a first one of the third inputs and a first one of the third outputs, and the second capacitor is coupled between a second one of the third inputs and a second one of the third outputs.

18. The system of claim 17, wherein the first one of the third inputs and the first one of the third outputs have opposite polarities, and the second one of the third inputs and the second one of the third outputs have opposite polarities.

19. The system of claim 15, further comprising:
a third amplifier having a third input and a third output, the third input coupled to the second output; and
a fourth amplifier having fourth inputs and a fourth output, the fourth inputs coupled to the third inputs, and the fourth output coupled to the second output.

20. The system of claim 19, further comprising:
a fifth amplifier having fifth inputs and fifth outputs, the fifth inputs coupled to the second inputs;
a notch filter having filter inputs and filter outputs;
a third chopper circuit coupled between the fifth outputs and the filter inputs; and
a sixth amplifier having sixth inputs and sixth outputs, the sixth inputs coupled to the filter outputs, and the sixth outputs coupled to the first outputs.
